(19) United States
(12) Patent Application Publication
(10) Pub. No.: US 2024/0363642 A1
(43) Pub. Date: Oct. 31, 2024

(54) ARRAY SUBSTRATE, PREPARATION METHOD THEREOF AND DISPLAY DEVICE

(71) Applicant: HKC CORPORATION LIMITED, Shenzhen (CN)

(72) Inventors: Hejing Zhang, Shenzhen (CN); Zhen Liu, Shenzhen (CN); Jie Zhang, Shenzhen (CN); Lidan Ye, Shenzhen (CN)

(21) Appl. No.: 18/641,266

(22) Filed: Apr. 19, 2024

(30) Foreign Application Priority Data
Apr. 27, 2023 (CN) 202310466042.3

(51) Int. Cl. H01L 27/12; G02F 1/1362

(52) U.S. Cl. CPC H01L 27/124; G02F 1/136286; H01L 27/1288; H01L 27/1248

(57) ABSTRACT

The present application provides an array substrate, a preparation method thereof, and a display device. The array substrate includes a base substrate, a first metal layer, a first insulation layer, a second metal layer, a second insulation layer, and a semiconductor layer. The first metal layer includes a data line, and the second metal layer includes a gate, a scanning line, and a common electrode. The gate is electrically connected to the scanning line. The semiconductor layer includes an active layer and a pixel electrode. The active layer includes a channel region, a source, and a drain, to overlap with the gate to form a driving transistor. The source is electrically connected to the data line through a conductive via hole, and the pixel electrode is electrically connected to the drain. The array substrate is able to effectively reduce parasitic capacitance, which facilitates to improve refresh rate and resolution.

### CROSS REFERENCE TO RELATED APPLICATIONS

This application claims priority to Chinese Patent Application No. 202310466042.3, filed Apr. 27, 2023, titled “Array substrate, preparation method thereof and display device”, which is herein incorporated by reference in its entirety.

### TECHNICAL FIELD

The present disclosure relates to the field of display technologies, and in particular, to an array substrate, a preparation method of the array substrate and a display device.

### BACKGROUND

In recent years, a thin film transistor liquid crystal display (TFT-LCD) has become a mainstream display product due to advantages of low radiation, low power consumption, low space occupancy, light weight, and aesthetics.

At present, on a traditional array substrate, a data line is located between adjacent pixels to provide data signals to pixels. However, there is often a large lateral parasite capacitance Cpd between a data line and a pixel electrode. The lateral parasite capacitance Cp is prone to generate signal crosstalk, which is extremely unfavorable for improving refresh rate and resolution of the display device.

### SUMMARY OF THE DISCLOSURE

A first technical solution provided in the present disclosure is an array substrate. The array substrate includes a base substrate, a first metal layer, a first insulation layer, a second metal layer, a second insulation layer and a semiconductor layer. The first metal layer is arranged on a side of the base substrate. The first insulation layer is arranged on a side of the first metal layer away from the base substrate. The second metal layer is arranged on a side of the first insulation layer away from the base substrate. The second insulation layer is arranged on a side of the second metal layer away from the base substrate. The semiconductor layer is arranged on a side of the second insulating layer away from the base substrate. The first metal layer includes a data line. The second metal layer includes a gate, a scanning line, and a common electrode. The gate is electrically connected to the scanning line. A projection of the common electrode on the base substrate covers a projection of the data line on the base substrate. The semiconductor layer includes an active layer and a pixel electrode. The active layer includes a channel region, a source, and a drain to overlap with the gate to form a driving transistor. The source is electrically connected to the data line through a conductive via hole, and the pixel electrode is electrically connected to the drain.

A second technical solution provided in the present disclosure is a preparation method of an array substrate. The preparation method includes the following operations. Providing a base substrate; preparing a first metal layer on a side of the base substrate and patterning the first metal layer to form a data line. Preparing a first insulation layer on a side of the first metal layer away from the base substrate. Preparing a second metal layer on a side of the first insulation layer away from the base substrate, and patterning the second metal layer to form a gate, a scanning line, and a common electrode; the gate is electrically connected to the scanning line, and a projection of the common electrode on the base substrate covers a projection of the data line on the base substrate. Preparing a second insulation layer on a side of the second metal layer away from the base substrate. Preparing a semiconductor layer on a side of the second insulation layer away from the base substrate, and forming a pixel electrode and an active layer on the semiconductor layer; and allowing the active layer to include a channel region, a source, and a drain, so as to overlap with the gate to form a driving transistor; the source is electrically connected to the data line through a conductive via hole, and the pixel electrode is electrically connected to the drain.

A third technical solution provided in the present disclosure is a display device. The display device includes a display panel and a backlight module. The display panel is configured to display an image. The display panel includes the array substrate as described above, or prepared by the preparation method as described above. The backlight module is arranged opposite to the display panel, and is configured to provide backlight to the display panel.

### BRIEF DESCRIPTION OF THE DRAWINGS

In order to provide a clearer explanation of the technical solution in embodiments of the present disclosure, a brief introduction will be given to the accompanying drawings required in the description of the embodiments. It is evident that the accompanying drawings in the following description are only some embodiments of the present disclosure. For ordinary technical personnel in the art, other accompanying drawings may be obtained based on these drawings without any creative efforts.

FIG. 1 is a planar structural schematic view of an array substrate according to an embodiment of the present disclosure.

FIG. 2 is a cross-sectional structural schematic view along an A-B direction of the array substrate shown in FIG. 1.

FIG. 3 is a structural schematic view of a display device according to an embodiment of the present disclosure.

FIG. 4 is a flowchart of a preparation method of an array substrate according to an embodiment of the present disclosure.

FIG. 5 is a schematic view of a process flowchart of the preparation method according to the embodiment of FIG. 4.

FIG. 6 is a process flowchart of operation S6 in FIG. 4.

FIG. 7 is a schematic view of the preparation process flowchart of operation S6 in FIG. 6.

### DETAILED DESCRIPTION

The following is a detailed explanation of technical solutions in embodiments of the present disclosure, combined with the accompanying drawings of the specification.

In the following description, specific details such as specific system structure, interfaces, technologies, etc., are proposed for the purpose of illustration rather than limitation, in order to fully understand the present disclosure.

The following will provide a clear and complete description of the technical solution in the embodiments of the present disclosure in conjunction with the accompanying drawings. Obviously, the described embodiments are only a part of the embodiments of the present disclosure, but not all of them. Based on the embodiments of the present disclosure, all other embodiments obtained by ordinary technical personnel in the art without creative efforts fall within the protection scope of the present disclosure.

The terms “first,” “second,” and “third” in the present disclosure are only used for descriptive purposes and cannot be understood as indicating or implying relative importance or implying the quantity of technical features indicated. Therefore, features limited to “first”, “second”, and “third” may explicitly or implicitly include at least one of these features. In the description of the present disclosure, “multiple” means at least two, such as two, three, etc., unless otherwise specified. All directional indications (such as up, down, left, right, front, rear . . . ) in the embodiments of the present disclosure are only configured to explain the relative position relationship, motion situation, etc., between components in a specific posture (as shown in the attached drawings). If the specific posture changes, the directional indication also changes accordingly. In addition, the terms “including” and “having”, as well as any variations of them, are intended to cover non-exclusive inclusions. For example, a process, method, system, product, or device that includes a series of operations or units is not limited to the listed operations or units, but optionally includes operations or units that are not listed, or optionally includes other operations or units that are inherent to these processes, methods, products, or devices.

The reference to “embodiment” in the present disclosure means that specific features, structures, or characteristics described in conjunction with the embodiment may be included in at least one embodiment of the present disclosure. The phrase appearing in various positions in the specification does not necessarily refer to the same embodiment, nor is it an independent or alternative embodiment that is mutually exclusive with other embodiments. Ordinary technical personnel in the art explicitly and implicitly understand that the embodiments described in the present disclosure may be combined with other embodiments.

The following provides a detailed explanation of the present disclosure in conjunction with the accompanying drawings and embodiments.

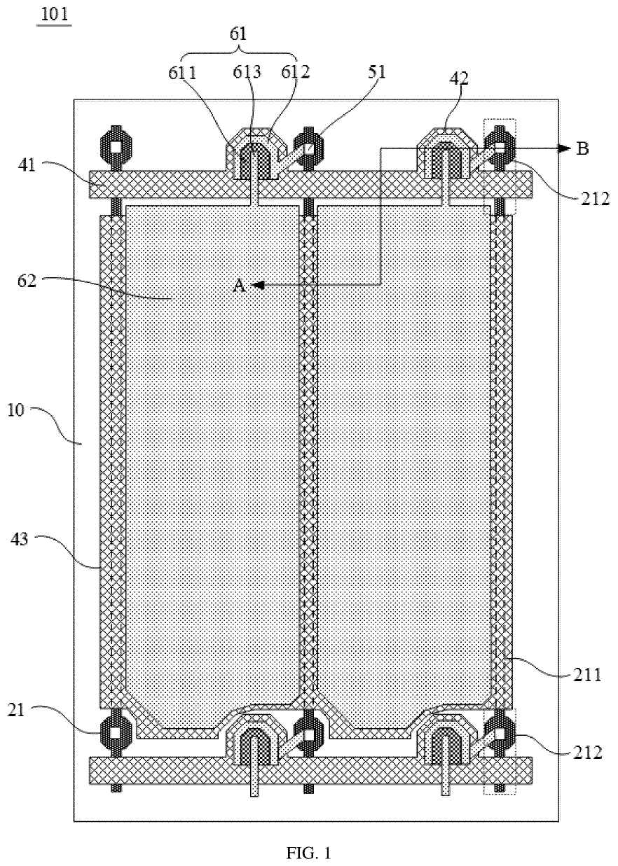

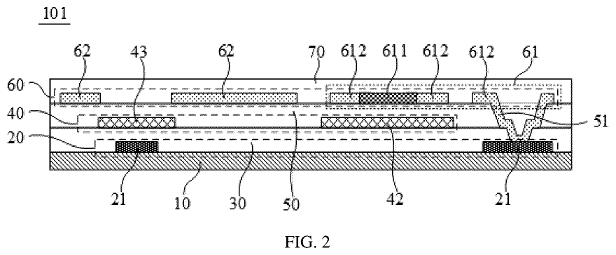

As illustrated in FIG. 1 and FIG. 2, FIG. 1 is a planar structural schematic view of an array substrate according to an embodiment of the present disclosure, and FIG. 2 a cross-sectional structural schematic view along an A-B direction of the array substrate shown in FIG. 1. In an embodiment, an array substrate 101 is provided. The array substrate 101 is a thin film transistor array substrate 101 and may be applied to display products such as liquid crystal display panels and electrophoresis display panels. The array substrate 101 includes a base substrate 10, a first metal layer 20, a first insulation layer 30, a second metal layer 40, a second insulation layer 50, and a semiconductor layer 60 sequentially stacked together.

In some embodiments, the base substrate 10 is configured to carry and protect various components and signal wirings on the array substrate 101. The base substrate 10 may be a rigid substrate or a flexible substrate. The base substrate 10 may be specifically made of a material with insulation and high temperature resistance, such as glass, resin or polyimide.

In some embodiments, the first metal layer 20 is arranged on a side of the base substrate 10. The first metal layer 20 includes a plurality of data lines 21. The plurality of data lines 21 are spaced and parallel and are configured to transmit data drive signals.

The second metal layer 40 includes a gate 42, multiple scanning lines 41, and a common electrode 43. The multiple scanning lines 41 are spaced and parallel. A projection of the scanning lines 41 on the base substrate 10 is perpendicular to a projection of the data line 21 on the base substrate 10, forming multiple subpixel regions arranged in an array. Each subpixel region corresponds to a driving transistor. The gate 42 of the second metal layer 40 is the gate 42 of the driving transistor. The gate 42 is electrically connected to the corresponding scanning lines 41, so as to enable the scanning lines 41 to transmit scanning driving signals to the driving transistor. A projection of the common electrode 43 on the base substrate 10 covers the projection of the data line 21 on the base substrate 10.

The semiconductor layer 60 includes an active layer 61 and a pixel electrode 62. The active layer 61 includes a channel region 611, a source 612, and a drain 613. The active layer 61 is overlapped with the gate 42 to form the aforementioned driving transistor. The source 612 is electrically connected to the data line 21 through a conductive via hole 51 running through the first insulation layer 30 and the second insulation layer 50, and the drain 613 is electrically connected to the pixel electrode 62, so as to form a pixel driving circuit. In some embodiments, the source 612 covers the conductive via hole 51, so as to be electrically connected to the data line 21, thus saving a process of arranging a conductive layer inside the conductive via hole 51.

In the present embodiment, the first metal layer 20 includes the data line 21, the semiconductor layer 60 includes the pixel electrode 62, and the second metal layer 40 where the common electrode 43 is arranged between the first metal layer 20 and the semiconductor layer. Therefore, a distance between the data line 21 and the pixel electrode 62 is increased, effectively reducing the parasitic capacitance Cpd between the data line 21 and the pixel electrode 62, without the need for an additional film layer or an additional process. Further, the common electrode 43 is arranged between the data line 21 and the pixel electrode 62, and the projection of the common electrode 43 on the base substrate 10 covers the projection of the data line 21 on the base substrate 10, resulting in that the common electrode 43 covers and is above the data line 21, which may basically shield all parasitic capacitance between the data line 21 and the pixel electrode 62, thereby improving the shielding effect between the data line 21 and the pixel electrode 62. This effectively reduces the signal crosstalk caused by the parasitic capacitance to the pixel electrode 62, and facilitates to improve the refresh rate and the resolution of the display device. In addition, the semiconductor layer 60 includes the pixel electrode 62 and the active layer 61, and the active layer 61 includes the channel region 611, the source 612, and the drain 613. The active layer 61 overlaps with the gate 42 to form a driving transistor, the channel region 611, the source 612, and the drain 613 of the driving transistor are arranged in a same layer as the pixel electrode 62. It not only reduces the number of via holes and film layers, but also simplifying a manufacturing process of array substrate 101 through a same preparation process, improving production efficiency and reducing production costs.

As shown in FIG. 2, in the present embodiment, the active layer 61 includes the channel region 611, the source 612, and the drain 613 integrated together. A material of the channel region 611 is a metal oxide semiconductor, and a material of the source 612 and the drain 613 is a conductive metal oxide semiconductor. In some embodiments, the channel region 611, the source 612, and the drain 613 are integrated together, with the source 612 and the drain 613 located on each side of the channel region 611. The material of the channel region 611 is a metal oxide semiconductor, such as amorphous indium gallium zinc oxide (IGZO), amorphous indium gallium tin oxide (IGTO), amorphous indium tin zinc oxide (ITZO), or amorphous indium gallium zinc tin oxide (IGZTO), which may be selected according to actual needs without specific restrictions. It should be noted that the conductive metal oxide semiconductor in the embodiments of the present disclosure refers to a material obtained after the conductive treatment of the aforementioned metal oxide semiconductor.

In the present embodiment, the channel region 611, the source 612, and drain 613 are an integrated structure, and the materials of the source 612 and the drain 613 are the same as that of channel region 611 through conductive treatment, such that a pattern of the channel region 611, the source 612, and the drain 613 may be patterned in a same process. The source 612 and the drain 613 only need to be one-step formed with the channel region 611. There is no need to reserve additional space for machine alignment accuracy for the preparation of source 612 and drain 613, and there is no deviation between design values of the source 612 and the drain 613 and their actual values. Therefore, a length of the channel region 611 may be effectively reduced, thereby reducing a size of the driving transistor and improving a pixel opening rate. The traditional array substrate 101, the source 612 and the drain 613 require additional metal patterns to be formed, and are prepared through different processes with channel region 611. Therefore, when preparing the source 612 and the drain 613, it is necessary to consider the machine alignment accuracy and the deviation between the design values and their actual values. As a result, for the channel length, there is a need to reserve a certain space to solve the alignment problem, such that the length of channel region 611 is not capable of being reduced. At the same time, in order to ensure that a TFT has a large on state current, a TFT size is usually arranged to be large, which will occupy some of the opening area, limiting the improvement of the opening ratio. Even if the metal oxide semiconductor with high electron mobility (such as IGZO) is adopted, the channel length of the TFT will still be greater than 6 μm, which is not able to significantly reduce the size of the TFT, and the improvement of the pixel opening ratio is relatively limited. The embodiments of the present disclosure may solve the technical problem through the above settings, effectively reducing the length of the channel region 611 and reducing the size of the driving transistor while ensuring a large open state current of the driving transistor, thereby significantly improving the pixel opening rate.

In some embodiments, a length range of the channel region 611 may be from 1.5 to 5.0 μm, which means that the length of the channel region 611 may even below 2.5 μm, significantly reducing the size of the driving transistor and effectively improving the pixel opening rate. In some embodiments, the length of channel region 611 may be 1.5 μm, 1.7 μm, 2.0 μm, 2.3 μm, 2.5 μm, 2.7 μm, 2.9 μm, 3.0μ, 3.2 μm, 3.5 μm, 3.7 μm, 3.9 μm, 4.0 μm, 4.2 μm, 4.4 μm, 4.6 μm, 4.8 μm, 4.9 μm or 5.0 μm, which may be set according to actual needs without specific restrictions.

In some embodiments, the pixel electrode 62 and the active layer 61 are arranged in the same layer. The material of the pixel electrode 62 is also a conductive metal oxide semiconductor. Therefore, the pixel electrode 62 and the active layer 61 may be formed through a same photomask patterning, which may reduce an additional process of preparing the pixel electrode 62. The pixel electrode 62 and the drain 613 may also be electrically connected through patterned wiring in a same process, without the need for cross layer connections through holes, which improves reliability of electrical connections. Meanwhile, due to the patterning of the pixel electrode 62 and the active layer 61 through the same photomask process, there is no need to consider the issue of the alignment accuracy or deviation between the design values and the actual values of the electrical connection between the pixel electrode 62 and the drain 613, which may further improve the pixel opening rate.

In some embodiments, the array substrate 101 also includes a passivation protection layer 70. The passivation protection layer 70 is arranged on a side of the semiconductor layer 60 away from the base substrate 10. The passivation protection layer 70 covers the semiconductor layer 60, so as to protect the active layer 61 and the pixel electrode 62 of the semiconductor layer 60, preventing a performance of the source layer 61 and the pixel electrode 62 from being affected by external water and oxygen. And in particular, the passivation protection layer 70 prevents the channel region 611 from being affected by water and oxygen, which may lead to conduction of the channel region 611, thus affecting switching effect of the driving transistor.

As shown in FIG. 1, in some embodiments, the data line 21 includes a first part 211 and a second part 212. A part of the data line 21 corresponding to the driving transistor is the second part 212, and a remaining part of the data line 21 is the first part 211. A projection of the common electrode 43 on the base substrate 10 covers a projection of the first part 211 on the base substrate 10. The conductive via hole 51 is located in an area where the second part 212 is located and runs through the first insulation layer 30 and the second insulation layer 50, such that the source 612 is electrically connected to the data line 21 through the conductive via hole 51. In some embodiments, the common electrode 43 does not fully cover the data line 21. In an area of the data line 21 opposite the driving transistor, the common electrode 43 does not cover the data line 21, so as to expose the data line 21. The conductive via hole 51 is arranged in the exposed area of the data line 21. The conductive via hole 51 runs through the first insulation layer 30 and the second insulation layer 50, and connects the source 612 and the data line 21. Thus, the data line 21 may transmit data drive signals to the pixel electrode 62 through the driving transistor.

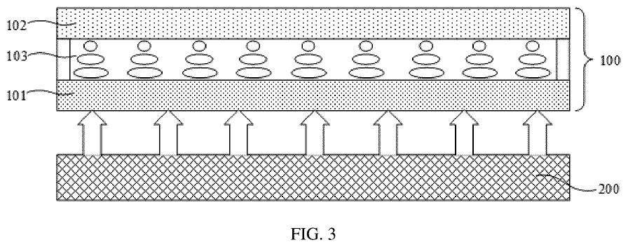

As illustrated in FIG. 3, which is a structural schematic view of the display device according to an embodiment of the present disclosure. In an embodiment, a display device is provided. The display device includes a display panel 100 and a backlight module 200 arranged opposite to the display panel 100. The backlight module 200 is configured to provide backlight to the display panel 100. The backlight module 200 may be a straight down backlight module 200 or a side in backlight module 200, which may be arranged according to actual needs without specific restrictions.

In some embodiments, the display panel 100 includes an array substrate 101, a counter substrate 102, and a dielectric layer 103. The display panel 100 is arranged opposite to the counter substrate 102, forming a closed storage space. The dielectric layer 103 is arranged in the storage space. The dielectric layer 103 may be a liquid crystal layer or an electrophoretic layer, and a driving electric field may be formed between the array substrate 101 and the counter substrate 102 to drive the liquid crystal layer to rotate or charged particles in the electrophoretic layer to move, thereby displaying an image.

In some embodiments, a specific structure and function of the array substrate 101 is the same or similar to a specific structure and function of the array substrate 101 mentioned in the previous embodiments, and may achieve the same technical effect. Details of the introduction are illustrated above, and will not be repeated here. The specific preparation method of the array substrate 101 may be obtained through the following operations. Please refer to the specific instructions below for the specific preparation method, which will not be introduced here.

The display device according to some embodiments may effectively reduce the parasitic capacitance between the pixel electrode 62 and the data line 21, reduce the signal crosstalk, and facilitate to improve the refresh rate and resolution of the display device. Meanwhile, it may increase the open state current of the driving transistor, reduce the size of the driving transistor, and significantly improve the pixel opening rate.

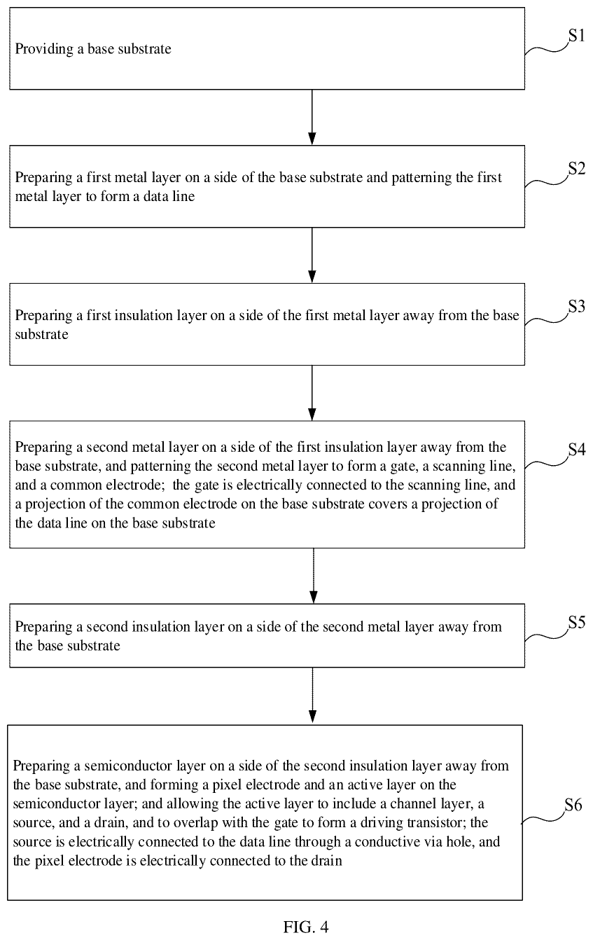

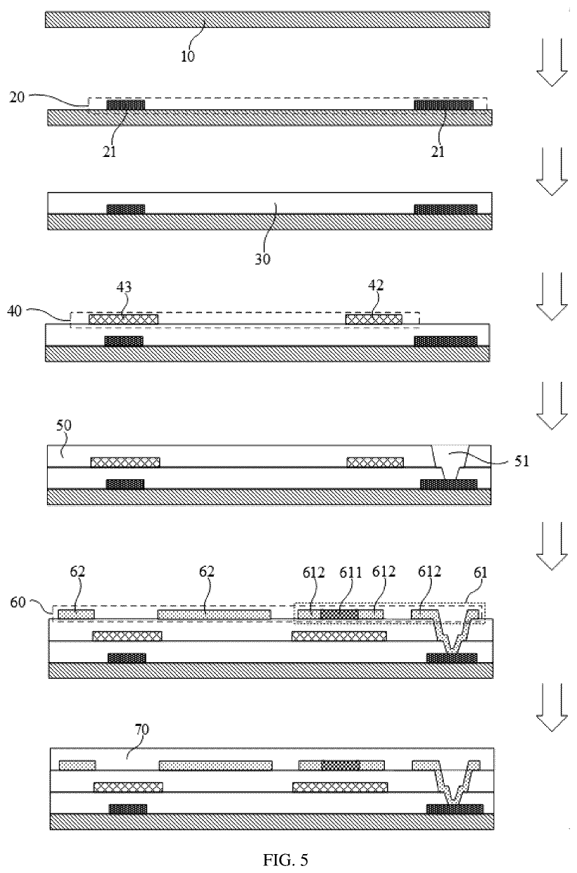

As illustrated in FIG. 4 and FIG. 5, FIG. 4 is a flowchart of the preparation method of the array substrate according to an embodiment of the present disclosure, and FIG. 5 is a flowchart of the preparation method according to the embodiment of FIG. 4. In the present embodiment, a preparation method of an array substrate 101 is provided for preparing the array substrate 101 described above. The preparation method includes the following operations.

S1: providing a base substrate 10.

S2: preparing a first metal layer 20 on a side of the base substrate 10 and patterning the first metal layer 20, to form a data line 21.

S3: preparing a first insulation layer 30 on a side of the first metal layer 20 away from the base substrate 10.

S4: preparing a second metal layer 40 on a side of the first insulation layer 30 away from the base substrate 10, and patterning the second metal layer 40 to form a gate 42, a scanning line 41, and a common electrode 43. The gate 42 is electrically connected to the scanning line 41, and a projection of the common electrode 43 on the base substrate 10 covers a projection of the data line 21 on the base substrate 10.

S5: preparing a second insulation layer 50 on a side of the second metal layer 40 away from the base substrate 10.

S6: preparing a semiconductor layer 60 on a side of the second insulation layer 50 away from the base substrate 10, and forming a pixel electrode 62 and an active layer 61 on the semiconductor layer 60. The active layer 61 includes a channel region 611, a source 612, and a drain 613, which are overlapped with the gate electrode 42 to form a driving transistor. The source 612 is electrically connected to the data line 21 through a conductive via hole 51, and the pixel electrode 62 is electrically connected to the drain 613.

In some embodiments, the patterning method involved in the above operations may be achieved through photomask exposure, development, etching, and photoresist stripping, or by photomask evaporation, which may be selected as needed.

The structure and function of the data line 21 and the scanning line 41 are the same or similar to that of the data line 21 mentioned in the previous embodiments, and may achieve the same technical effect. For details, please refer to the specific introduction above, which will not be repeated here. The materials of the data line 21, the scanning line 41, the gate 42, and the common electrode 43 may be Mo/Cu, Ti/Cu, Mo/Al/Mo, Al/Mo, or Mo/Ti/Cu, and their thickness and shape may be arranged according to actual needs.

The first insulation layer 30 and the second insulation layer 50 are configured to isolate adjacent metal layers, such that short circuits between adjacent metal layers may be avoided. Materials of the first insulation layer 30 and the second insulation layer 50 may be silicon nitride or silicon oxide, and their thickness may be arranged according to actual needs.

In some embodiments, by forming the data line 21 on the first metal layer 20, the scanning line 41, the gate 42, and the common electrode 43 on the second metal layer 40, and forming the pixel electrode 62 and the active layer 61 on the semiconductor layer 60, a distance between the data line 21 and the pixel electrode 62 is increased. Therefore, the parasitic capacitance Cpd between the data line 21 and the pixel electrode 62 is effectively reduced, without the need for an additional film layer or an additional process. Further, by arranging the common electrode 43 between the data line 21 and the pixel electrode 62, and covering the common electrode 43 above the data line 21, all parasitic capacitances between the data line 21 and the pixel electrode 62 may be basically shielded, which improves the shielding effect between the data line 21 and the pixel electrode 62, thus effectively reducing the signal crosstalk caused by the parasitic capacitance to the pixel electrode 62, and facilitates to improving the refresh rate and resolution of the display device. In addition, a pixel electrode 62 and an active layer 61 are formed in the semiconductor layer 60, and the active layer 61 includes the channel region 611, the source 612, and the drain 613, so as to overlap with the gate electrode 42 to form the driving transistor. The channel region 611, the source 612, and the drain 613 of the driving transistor are arranged in the same layer as the pixel electrode 62, which not only reduces the number of via holes and film layers, but also simplifies the process of array substrate 101 through the same process of preparation, improving production efficiency and reducing production costs.

In some embodiments, the patterning processing of the pixel electrode 62, the channel region 611, the source 612, and the drain 613 may be achieved in the same process through photomask, which not only reduces the processes and the use of photomask, but also eliminates the need to reserve space for the separate preparation of the pixel electrode 62, the source 612, and the drain 613 to consider the accuracy of machine alignment. There will also be no deviation between the design values of the positions of the source 612 and the drain 613 and their actual values, which may effectively reduce the length of the channel region 611, thereby reducing the size of the driving transistor and improving the pixel opening rate.

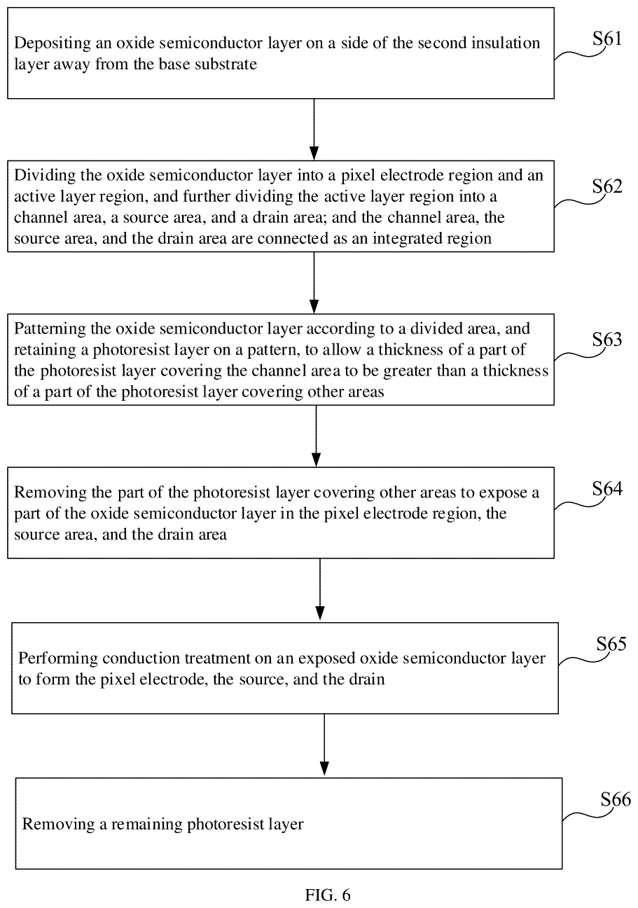

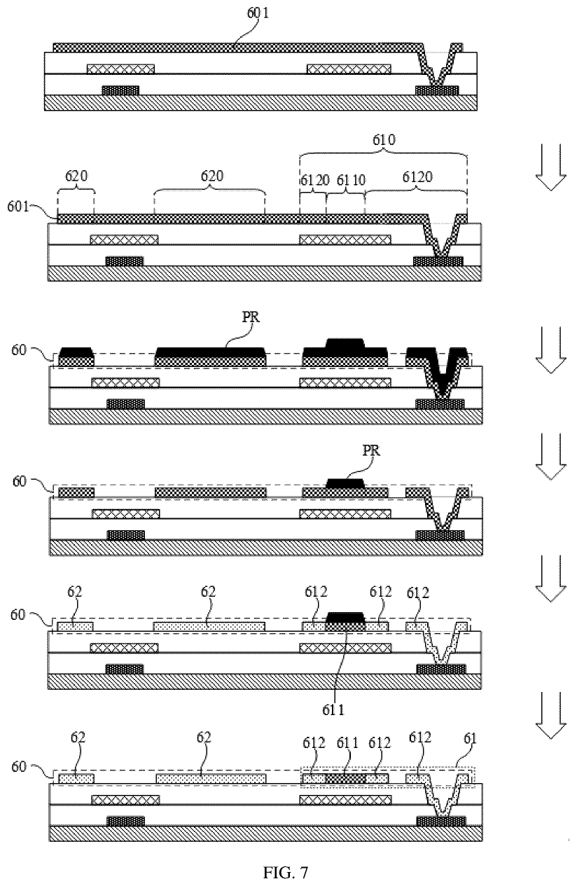

As illustrated in FIG. 6 and FIG. 7, FIG. 6 is a flowchart of operation S6 in FIG. 4, and FIG. 7 is a flowchart of a preparation process of operation S6 in FIG. 6. In some embodiments, operation S6 includes the following operations.

S61: depositing an oxide semiconductor layer 601 on a side of the second insulation layer 50 away from the base substrate 10.

S62: dividing the oxide semiconductor layer 601 into a pixel electrode region 620 and an active layer region 610, and further dividing the active layer region 610 into a channel region 6110, a source area 6120, and a drain area (not shown in the drawings). The channel region 6110, the source area 6120, and the drain area are connected as a whole region.

S63: patterning the oxide semiconductor layer 601 according to the divided area, and retaining a photoresist layer on the pattern, such that a thickness of the photoresist layer covering the channel region 6110 is greater than that covering other areas.

S64: removing the photoresist layer covering other areas to expose a partial oxide semiconductor layer 601 on the pixel electrode region 620, the source electrode area 6120, and the drain electrode area.

S65: conducting the exposed oxide semiconductor layer 601 to form the pixel electrode 62, the source 612, and the drain 613.

S66: removing the remaining photoresist layer.

In some embodiments, a two-tone method is adopted. The first operation is coating and patterning the oxide semiconductor layer 601 to form the patterned active layer 61 and the pixel electrode 62. The second operation is performing conduction treatment on the oxide semiconductor layer 601 outside the channel region 6110, so as to form the conductive pixel electrode 62, the source 612, and the drain 613.

In some embodiments, after coating and patterning the oxide semiconductor layer 601, the photoresist is retained and may be exposed through a semi-transparent photomask, such that a thickness of the photoresist above the channel region 611 is greater than that of the photoresist in other regions. The photoresist may be either positive or negative, and may be selected according to actual needs. The thickness of the photoresist above channel region 611 is greater than that of the photoresist in other regions. In the second operation, operation S64, when removing the photoresist, the thickness of the photoresist above channel region 611 is greater than that of the photoresist in other regions, such that a certain thickness of photoresist layer may still be retained above the channel region 611. Therefore, in subsequent operations, when performing conduction treatment on the oxide semiconductor layer 601 of other regions does not affect the channel region 611, and will not cause the conduction of the channel region 611. In some embodiments, the conduction treatment may be carried out by dry etching with ion bombardment or ion implantation to improve conductivity of the pixel electrode 62, the source 612, and the drain 613.

In some embodiments, the material of the oxide semiconductor layer 601 may be a metal oxide semiconductor material, such as amorphous indium gallium zinc oxide (IGZO), amorphous indium gallium tin oxide (IGTO), amorphous indium tin zinc oxide (ITZO), or amorphous indium gallium zinc tin oxide (IGZTO), etc., which may be arranged according to actual needs without specific limitations.

By adopting metal oxide semiconductor as the material of the oxide semiconductor layer 601, not only the open state current of the driving transistor may be significantly increased, but also the length of the channel region 611 and the size of the driving transistor may be reduced, thereby effectively improving the pixel opening rate. In some embodiments, by adopting the above method, the length of the channel region 611 may be reduced to 1.5-5.0 μm, or even below 2.5 μm, such as 5.0 μm, 4.9 μm, 4.8 μm, 4.6 μm, 4.4 μm, 4.2 μm, 4.0 μm, 3.9 μm, 3.7 μm, 3.5 μm, 3.2 μm, 3.0 μm, 2.9 μm, 2.7 μm, 2.5 μm, 2.4 μm, 2.3 μm, 2.2 μm, 2.1 μm, 2.0 μm, 1.9 μm, 1.8 μm, 1.7 μm, 1.6 μm, or 1.5 μm, etc., which may effectively reduce the size of the driving transistor, thereby significantly improving the pixel opening rate.

In some embodiments, the data line 21 includes the first part 211 and the second part 212 (as shown in FIG. 1), with the part of the data line 21 corresponding to the driving transistor being the second part 212, and the remaining part being the first part 211. At operation S4, the projection of the common electrode 43 on the base substrate 10 covers the projection of the first part 211 on the base substrate 10. In other words, the common electrode 43 does not fully cover the data line 21, and in an area opposite the driving transistor of the data line 21, the common electrode 43 does not cover the data line 21, so as to expose the data line 21. A position is reserved for arranging the conductive through hole 51, such that the conductive through hole 51 passes through the first insulation layer 30 and the second insulation layer 50, and connecting the source 612 and the data line 21, thereby the data line 21 may transmit the data driving signal to the pixel electrode 62 through the driving transistor.

Therefore, after operation S5, an operation of arranging the conductive via hole 51 is also included.

Forming the conductive via hole 51 on the second insulation layer 50, and making the conductive via hole 51 penetrate the second insulation layer 50 and the first insulation layer 30, and electrically connecting the conductive via hole 51 to the data line 21.

At operation S6, it is also necessary to extend the source 612 of the driving transistor to the conductive via hole 51, such that the source 612 is electrically connected to the data line 21 through the conductive via hole 51. In some embodiments, by extending the source 612 and covering the conductive via hole 51 to be electrically connected to the data line, the process of arranging a conductive layer inside the conductive via hole 51 may be saved.

Through the above operations, without affecting the shielding effect of the common electrode 43, the common electrode 43 does not cover the part of the data line 21 corresponding to the driving transistor to expose the data line 21, thus the electrical connection between the data line 21 and the source 612 is achieved through the conductive through hole 51.

Furthermore, the preparation method includes the following operations.

S7: preparing a passivation protective layer 70 on a side of the semiconductor layer 60 away from the base substrate 10.

By arranging a passivation protection layer 70 and covering the active layer 61 and pixel electrode 62 with the passivation protection layer 70, the active layer 61 and pixel electrode 62 of the semiconductor layer 60 are protected to prevent external water and oxygen from affecting the performance of the active layer 61 and pixel electrode 62, especially the performance of the channel region 611. This prevents the channel region 611 from being affected by water and oxygen, which may lead to conduction of the channel region 611 and affecting the switching effect of the driving transistor, thereby ensuring the stability of the performance of the driving transistor.

The above are only some embodiments of the present disclosure and do not limit the protection scope of the present disclosure. Any equivalent structure or equivalent process transformation made using the description and accompanying drawings of the present disclosure, or directly or indirectly applied in other related technical fields, are equally included in the protection scope of the present disclosure.

What is claimed is:

1. An array substrate, comprising:
a base substrate;
a first metal layer, arranged on a side of the base substrate;
a first insulation layer, arranged on a side of the first metal layer away from the base substrate;
a second metal layer, arranged on a side of the first insulation layer away from the base substrate;
a second insulation layer, arranged on a side of the second metal layer away from the base substrate; and
a semiconductor layer, arranged on a side of the second insulating layer away from the base substrate;
wherein the first metal layer comprises a data line, the second metal layer comprises a gate, a scanning line, and a common electrode; the gate is electrically connected to the scanning line, a projection of the common electrode on the base substrate covers a projection of the data line on the base substrate, the semiconductor layer comprises an active layer and a pixel electrode, the active layer comprises a channel region, a source, and a drain and overlaps with the gate to form a driving transistor, the source is electrically connected to the data line through a conductive via hole, and the pixel electrode is electrically connected to the drain.

2. The array substrate according to claim 1, wherein the active layer comprises the channel region, the source, and the drain integrated together; a material of the channel region is a metal oxide semiconductor, and a material of the source, the drain, and the pixel electrode is a conductive metal oxide semiconductor.

3. The array substrate according to claim 2, wherein a length range of the channel region is from 1.5 to 5.0 μm; the array substrate comprises a passivation protective layer, and the passivation protective layer is arranged on a side of the semiconductor layer away from the base substrate and covers the semiconductor layer.

4. The array substrate according to claim 1, wherein the data line comprises a first part and a second part, a part of the data line corresponding to the driving transistor is the second part, and a remaining part of the data line is the first part; a projection of the common electrode on the base substrate covers a projection of the first part on the base substrate; the conductive via hole is located in an area where the second part is located and runs through the first insulation layer and the second insulation layer, to allow the drain to be electrically connected to the data line through the conductive via hole.

5. The array substrate according to claim 1, wherein the source and the drain are located on each side of the channel region.

6. The array substrate according to claim 1, wherein the source covers the conductive via hole to be electrically connected to the data line.

7. The array substrate according to claim 2, wherein the pixel electrode and the active layer are arranged in a same layer, and a material of the pixel electrode is a conductive metal oxide semiconductor.

8. A preparation method of an array substrate, comprising:
providing a base substrate;
preparing a first metal layer on a side of the base substrate and patterning the first metal layer to form a data line;
preparing a first insulation layer on a side of the first metal layer away from the base substrate;
preparing a second metal layer on a side of the first insulation layer away from the base substrate, and patterning the second metal layer to form a gate, a scanning line, and a common electrode; wherein the gate is electrically connected to the scanning line, and a projection of the common electrode on the base substrate covers a projection of the data line on the base substrate;
preparing a second insulation layer on a side of the second metal layer away from the base substrate; and
preparing a semiconductor layer on a side of the second insulation layer away from the base substrate, and forming a pixel electrode and an active layer on the semiconductor layer; and
allowing the active layer to comprise a channel region, a source, and a drain, and to overlap with the gate to form a driving transistor; the source is electrically connected to the data line through a conductive via hole, and the pixel electrode is electrically connected to the drain.

9. The preparation method according to claim 8, wherein the preparing a semiconductor layer on a side of the second insulation layer away from the base substrate, and forming a pixel electrode and an active layer on the semiconductor layer comprises:
depositing an oxide semiconductor layer on a side of the second insulation layer away from the base substrate;
dividing the oxide semiconductor layer into a pixel electrode region and an active layer region, and further dividing the active layer region into a channel area, a source area, and a drain area; wherein the channel area, the source area, and the drain area are connected as an integrated region;
patterning the oxide semiconductor layer according to a divided area, and retaining a photoresist layer on a pattern, to allow a thickness of a part of the photoresist layer covering the channel area to be greater than a thickness of a part of the photoresist layer covering other areas;
removing the part of the photoresist layer covering other areas to expose a part of the oxide semiconductor layer in the pixel electrode region, the source area, and the drain area;
performing conduction treatment on an exposed oxide semiconductor layer to form the pixel electrode, the source, and the drain; and
removing a remaining photoresist layer.

10. The preparation method according to claim 9, wherein a material of the oxide semiconductor layer is a metal oxide semiconductor, and a length range of the channel area is 1.5-5.0 μm.

11. The preparation method according to claim 8, wherein the data line comprises a first part and a second part, a part of the data line corresponding to the driving transistor is the second part, and a remaining part of the data line is the first part;
wherein the preparing a second metal layer on a side of the first insulation layer away from the base substrate, and patterning the second metal layer to form a gate, a scanning line, and a common electrode comprises: allowing a projection of the common electrode on the base substrate to cover a projection of the first part on the base substrate.

12. The preparation method according to claim 8, wherein after the preparing a second insulation layer on a side of the second metal layer away from the base substrate, the preparation method further comprises:
forming the conductive via hole on the second insulation layer, to allow the conductive via hole to penetrate the second insulation layer and the first insulation layer, and electrically connect the conductive via hole to the data line;
the preparing a semiconductor layer on a side of the second insulation layer away from the base substrate, and patterning the semiconductor layer to form a pixel electrode and an active layer comprises: extending the source of the driving transistor to the conductive via hole to electrically connect the source to the data line through the conductive via hole; and
the preparation method further comprises: preparing a passivation protective layer on a side of the semiconductor layer away from the base substrate.

13. A display device, comprising:
a display panel, configured to display an image, and comprising an array substrate, wherein the array substrate comprises:
a base substrate;
a first metal layer, arranged on a side of the base substrate;
a first insulation layer, arranged on a side of the first metal layer away from the base substrate;
a second metal layer, arranged on a side of the first insulation layer away from the base substrate;
a second insulation layer, arranged on a side of the second metal layer away from the base substrate; and
a semiconductor layer, arranged on a side of the second insulating layer away from the base substrate;
wherein the first metal layer comprises a data line, the second metal layer comprises a gate, a scanning line, and a common electrode; the gate is electrically connected to the scanning line, a projection of the common electrode on the base substrate covers a projection of the data line on the base substrate, the semiconductor layer comprises an active layer and a pixel electrode, the active layer comprises a channel region, a source, and a drain and overlaps with the gate to form a driving transistor, the source is electrically connected to the data line through a conductive via hole, and the pixel electrode is electrically connected to the drain; and
a backlight module, arranged opposite to the display panel, and configured to provide backlight to the display panel.

14. The display device according to claim 13, wherein the active layer comprises the channel region, the source, and the drain integrated together; a material of the channel region is a metal oxide semiconductor, and a material of the source, the drain, and the pixel electrode is a conductive metal oxide semiconductor.

15. The display device according to claim 14, wherein a length range of the channel region is from 1.5 to 5.0 μm; the array substrate comprises a passivation protective layer, and the passivation protective layer is arranged on a side of the semiconductor layer away from the base substrate and covers the semiconductor layer.

16. The display device according to claim 13, wherein the data line comprises a first part and a second part, a part of the data line corresponding to the driving transistor is the second part, and a remaining part of the data line is the first part; a projection of the common electrode on the base substrate covers a projection of the first part on the base substrate; the conductive via hole is located in an area where the second part is located and runs through the first insulation layer and the second insulation layer, to allow the drain to be electrically connected to the data line through the conductive via hole.

17. The display device according to claim 13, the source and the drain are located on each side of the channel region.

18. The display device according to claim 13, wherein the source covers the conductive via hole to be electrically connected to the data line.

19. The display device according to claim 14, wherein the pixel electrode and the active layer are arranged in a same layer, and a material of the pixel electrode is a conductive metal oxide semiconductor.

20. The display device according to claim 14, further comprising:
a counter substrate, and
a dielectric layer;
wherein the display panel is arranged opposite to the counter substrate to form a closed storage space, and the dielectric layer is arranged in the storage space.
